(19) United States
(12) Patent Application Publication
(10) Pub. No.: US 2020/0257372 A1
(43) Pub. Date: Aug. 13, 2020

(54) OUT-OF-VOCABULARY GESTURE RECOGNITION FILTER

(71) Applicant: SAGE SENSES INC., Toronto (CA)

(72) Inventor: Arash ABGHARI, Kitchener (CA)

(21) Appl. No.: 16/786,272

(22) Filed: Feb. 10, 2020

Related U.S. Application Data
(60) Provisional application No. 62/803,655, filed on Feb. 11, 2019.

(51) Int. Cl. G06F 3/01; G06K 9/00; G01P 15/18; G01C 19/00; G01R 33/02; G01P 13/00

(52) U.S. Cl. CPC G06F 3/017; G06K 9/00335; G01P 13/00; G01C 19/00; G01R 33/02; G01P 15/18

(57) ABSTRACT

A method of gesture detection in a controller includes; storing, in a memory connected with the controller: (i) a primary inference model definition corresponding to a plurality of gesture identifiers, and (ii) a set of auxiliary model definitions, each corresponding to a respective one of the gesture identifiers; obtaining, at the controller, motion sensor data; selecting a candidate gesture identifier from the plurality of gesture identifiers, based on the motion sensor data and the primary inference model definition; validating the candidate gesture identifier using the auxiliary model definition that corresponds to the candidate gesture identifier; and when the candidate gesture identifier is validated, presenting the candidate gesture identifier.

### CROSS-REFERENCE TO RELATED APPLICATION

This application claims priority from U.S. provisional patent application No. 62/803655, filed Feb. 11, 2019, the contents of which is incorporated herein by reference.

### FIELD

The specification relates generally to gesture recognition, and specifically to a filter for out-of-vocabulary gestures in gesture recognition systems.

### BACKGROUND

Gesture-based control of various computing systems depends on the ability of the relevant system to accurately recognize a gesture, e.g. made by an operator of the system, in order to initiate the appropriate functionality. Detecting predefined gestures from motion sensor data (e.g. accelerometer and/or gyroscope data) may be computationally complex, and may also be prone to incorrect detections. An incorrectly detected gesture, in addition to consuming computational resources, may lead to incorrect system behavior by initiating functionality corresponding to a gesture that does not match the gesture made by the operator.

### SUMMARY

An aspect of the specification provides a method of gesture detection in a controller, comprising: storing, in a memory connected with the controller: (i) a primary inference model definition corresponding to a plurality of gesture identifiers, and (ii) a set of auxiliary model definitions, each corresponding to a respective one of the gesture identifiers; obtaining, at the controller, motion sensor data; selecting a candidate gesture identifier from the plurality of gesture identifiers, based on the motion sensor data and the primary inference model definition; validating the candidate gesture identifier using the auxiliary model definition that corresponds to the candidate gesture identifier; and when the candidate gesture identifier is validated, presenting the candidate gesture identifier.

Another aspect of the specification provides a computing device, comprising: a memory storing (i) a primary inference model definition corresponding to a plurality of gesture identifiers, and (ii) a set of auxiliary model definitions, each corresponding to a respective one of the gesture identifiers; a controller connected with the memory, the controller configured to: obtain motion sensor data; select a candidate gesture identifier from the plurality of gesture identifiers, based on the motion sensor data and the primary inference model definition; validate the candidate gesture identifier using the auxiliary model definition that corresponds to the candidate gesture identifier; and when the candidate gesture identifier is validated, present the candidate gesture identifier.

A further aspect of the specification provides a non-transitory computer-readable medium storing computer-readable instructions executable by a controller to: store (i) a primary inference model definition corresponding to a plurality of gesture identifiers, and (ii) a set of auxiliary model definitions, each corresponding to a respective one of the gesture identifiers; obtain motion sensor data; select a candidate gesture identifier from the plurality of gesture identifiers, based on the motion sensor data and the primary inference model definition; validate the candidate gesture identifier using the auxiliary model definition that corresponds to the candidate gesture identifier; and when the candidate gesture identifier is validated, present the candidate gesture identifier.

### BRIEF DESCRIPTIONS OF THE DRAWINGS

Embodiments are described with reference to the following figures, in which:

FIG. 1 is a block diagram of a computing device for gesture detection;

FIG. 2 is a flowchart of a method of gesture detection and validation; and

FIG. 3 is a schematic illustrating an example performance of the method of FIG. 2.

### DETAILED DESCRIPTION

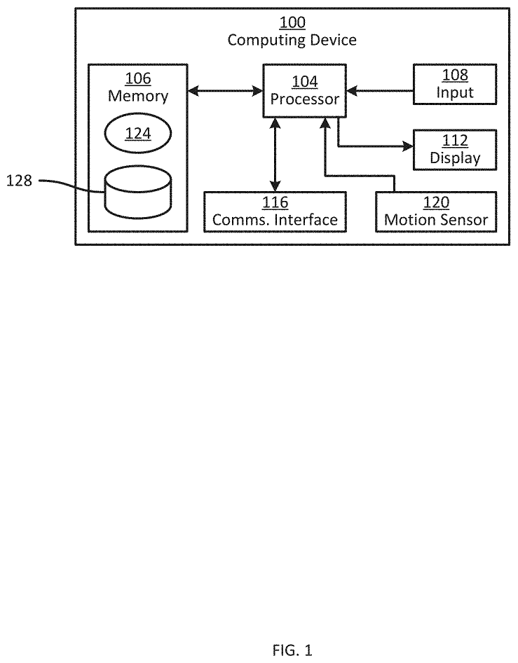

FIG. 1 depicts a computing device 100 for gesture detection. In general, the computing device 100 is configured to obtain motion sensor data indicative of a gesture made by an operator of the computing device 100, and to determine whether the motion sensor data corresponds to one of a set of preconfigured gestures. The motion sensor data can include any one of, or any suitable combination of, accelerometer and gyroscope measurements, e.g. from an inertial measurement unit (IMU), image data captured by one or more cameras, input data captured by a touch screen or other input device, or the like.

As will be discussed in greater detail below, the computing device 100 is configured to perform gesture detection in two stages. In a first stage, the computing device 100 applies a primary inference model (e.g. a classifier) to the motion sensor data in order to select a candidate one of the preconfigured gestures that appears to match the input motion sensor data. The first stage, however, may produce incorrect results at times. For example, the first stage may lead to a selection of a candidate gesture identifier when in fact, the gesture made by the operator (and represented by the motion sensor data) does not match any of the preconfigured gestures. Such a gesture (i.e. that does not match any of the preconfigured gestures) may also be referred to as an out-of-vocabulary (OOV) gesture.

The incorrect matching of a preconfigured gesture to motion sensor data resulting from an OOV gesture can have various causes. For example, when the motion sensor data is obtained from an IMU and therefore includes acceleration measurements, gestures that are visually distinct may result in similar acceleration data. Another example cause of incorrect classification of an OOV gesture arises from the classification mechanism itself. For example, some classifiers are configured to generate probabilities that the motion sensor data matches each preconfigured gesture. The set of probabilities may be normalized to sum to a value of 1 (or 100%), and the normalization can lead to inflating certain probabilities.

To guard against incorrect matching of an OOV gesture to one of the preconfigured gestures, the computing device 100 stores auxiliary model definitions for each of the preconfigured gestures, in addition to the primary inference model mentioned above. The auxiliary model definition that corresponds to the candidate gesture identifier selected via primary classification is applied to the motion sensor data to validate the output of the primary inference model. When the validation is successful, functionality corresponding to the candidate gesture detection may be initiated, Otherwise, the candidate gesture detection may be discarded.

The computing device 100 includes a central processing unit (CPU), which may also be referred to as a processor 104 or a controller 104. The processor 104 is interconnected with a non-transitory computer readable storage medium, such as a memory 106. The memory 206 includes any suitable combination of volatile memory (e.g. Random Access Memory (RAM)) and non-volatile memory (e.g. read only memory (ROM), Electrically Erasable Programmable Read Only Memory (EEPROM), flash) memory. The processor 104 and the memory 106 each comprise one or more integrated circuits (ICs).

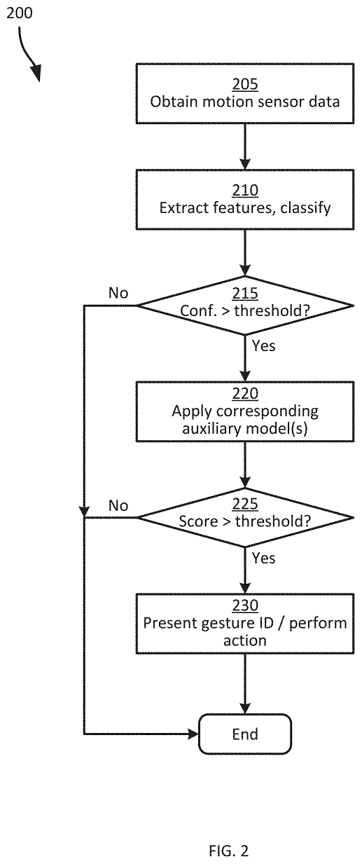

The computing device 100 also includes an input assembly 108 interconnected with the processor 104, such as a touch screen, a keypad, a mouse, or the like. The input assembly 108 illustrated in FIG. 2 can include more than one of the above-mentioned input devices. In general, the input assembly 108 receives input and provides data representative of the received input to the processor 104. The device 100 further includes an output assembly, such as a display 112 interconnected with the processor 104. When the input assembly 108 includes a touch screen, the display assembly 112 can be integrated with the touch screen. The device 100 can also include other output assemblies (not shown), such as speaker, an LED indicator, and the like. In general, the display 112, and any other output assembly included in the device 100, is configured to receive output from the processor 104 and present the output, e.g. via the emission of sound from the speaker, the rendering of graphical representations on the display 112, and the like.

The device 100 further includes a communications interface 116, enabling the device 100 to exchange data with other computing devices, e.g. via a network. The communications interface 116 includes any suitable hardware (e.g. transmitters, receivers, network interface controllers and the like) allowing the device 100 to communicate according to one or more communications standards.

The device 100 also includes a motion sensor 120, including one or more of an accelerometer, a gyroscope, a magnetometer, and the like. In the present example, the motion sensor 120 is an inertial measurement unit (IMU) including each of the above-mentioned sensors. For example, the IMU typically includes three accelerometers configured to detect acceleration in respective axes defining three spatial dimensions (e.g. X, Y and Z). The IMU can also include gyroscopes configured to detect rotation about each of the above-mentioned axes. Finally, the IMU can also include a magnetometer. The motion sensor 120 is configured to collect data representing the movement of the device 100 itself, referred to herein as motion data, and to provide the collected motion data to the processor 104.

The components of the device 100 are interconnected by communication buses (not shown), and powered by a battery or other power source, over the above-mentioned communication buses or by distinct power buses (not shown).

The memory 106 of the device 100 stores a plurality of applications, each including a plurality of computer readable instructions executable by the processor 104. The execution of the above-mentioned instructions by the processor 104 causes the device 100 to implement certain functionality, as discussed herein. The applications are therefore said to be configured to perform that functionality in the discussion below. In the present example, the memory 106 of the device 100 stores a gesture detection application 124, also referred to herein simply as the application 124. The device 100 is configured, via execution of the application 124 by the processor 104, to obtain motion sensor data from the motion sensor 120 and/or the input assembly 108, and to detect whether the motion sensor data matches any of a plurality of preconfigured gestures.

As noted above, the detection functionality implemented by the device 100 relies on a primary inference model and a set of auxiliary models. Model definitions (e.g. parameters defining inference models and the like) are stored in the memory 106, particularly in a model definition repository 128. In particular, the repository 128 contains data defining the primary inference model (e.g. a Softmax classifier, a neural network classifier, or the like). The data defining the primary inference model, such as node weights and the like, are derived via a training process, in which the primary inference model is trained to recognize each of the preconfigured gestures mentioned earlier. Mechanisms for generating training data, as well as for training the primary inference model, are disclosed in Applicant's patent publication no. WO 2019/016764, the contents of which is incorporated herein by reference. Various other mechanisms for obtaining training data and training an inference model will also occur to those skilled in the art.

The primary inference model accepts inputs in the form of features extracted from the motion sensor data, and generates a set of probabilities according to the model definition mentioned above. The set of probabilities includes, for each preconfigured gesture for which the primary inference model has been trained, a probability that the input motion sensor data represents the preconfigured gesture.

While the primary inference model can be configured to distinguish between the preconfigured gestures, the auxiliary inference models are specific to each preconfigured gesture. That is, the repository 128 contains at least one auxiliary model definition for each preconfigured gesture.

A given auxiliary model accepts the above-mentioned features as inputs (e.g. the same set of features as are accepted by the primary inference model), and generates a likelihood that the input motion sensor data from which the features were extracted represents the preconfigured gesture. That is, while the primary inference model outputs a set of probabilities covering all preconfigured gestures (with the highest probability indicating the most likely match), each auxiliary model outputs only one likelihood, corresponding to one preconfigured gesture. In some examples, the auxiliary models are implemented as Hidden Markov Models (HMMs).

In some examples, there may be a number of auxiliary models for each preconfigured gesture, for example to generate likelihoods that certain aspects of the input data match certain aspects of the relevant preconfigured gesture. Aspects can include motion in specific planes, for example.

In other examples, the processor 104, as configured by the execution of the application 124, is implemented as one or more specifically-configured hardware elements, such as field-programmable gate arrays (FPGAs) and/or application-specific integrated circuits (ASICs).

The device 100 can be implemented as any one of a variety of computing devices, including a smartphone, a tablet computer, or a wearable device (e.g. integrated with a glove, a watch, or the like). In the illustrated example the device 100 itself collects motion sensor data and processes the motion sensor data. In other examples, however, the motion sensor data can be collected at another device such as a smartphone, wearable device or the like, and the device 100 can perform gesture recognition on behalf of that other device. In such examples, the device 100 may therefore also be implemented as a desktop computer, a server, or the like.

The functionality implemented by the device 100 will now be described in greater detail with reference to FIG. 2. FIG. 2 illustrates a method 200 of gesture detection, which will be described in conjunction with its performance by the device 100.

At block 205, the computing device 100 is configured to obtain motion sensor data. The motion sensor data can be obtained from the motion sensor 120, the input assembly 108 (e.g. a touch screen), or a combination thereof. In other examples, as noted earlier, the motion sensor data can be obtained via the communications interface 116, having been collected by another device via motion sensors of that device. The motion sensor data obtained at block 205 can therefore include IMU data in the form of time-ordered sequences of measurements from an accelerometer, gyroscope and magnetometer, touch data in the form of a time-ordered sequence of coordinates (e.g. in two dimensions, corresponding to the plane of the display 112), or a combination thereof.

At block 210, the device 100 is configured to extract features from the motion sensor data obtained at block 205, and to classify the motion sensor data according to the extracted features. The features extracted at block 210 correspond to the features employed to train the primary inference model. A wide variety of features can be extracted at block 210, some examples of which are discussed in Applicant's patent publication no. WO 2019/016764. Prior to feature extraction, the motion sensor data may also be preprocessed, for example as described in WO 2019/016764 to correct gyroscope drift, remove a gravity component from acceleration data, resample the motion sensor data at a predefined sample rate, and the like.

Example features extracted at block 210 include vectors containing time-domain representations of displacement, velocity and/or acceleration values. For example, the device 100 can extract three one-dimensional feature vectors, corresponding to X, Y and Z axes, each containing a sequence of acceleration values in the respective axis. In some examples, the features extracted at block 210 include a one-dimensional vector containing a sequence of angles of orientation, each indicating a direction of travel for the gesture during a predetermined sampling period. For example, for a gesture provided via a touch screen, an angle may be generated for a segment of the gesture by computing an inverse sine and/or inverse cosine based on the displacement in X and Y dimensions for that segment.

A further example feature vector is a one-dimensional histogram in which the bins are angles of orientation, as determined above. Thus, the device 100 can generate vectors containing angle-of-orientation histograms for each plane of motion.

In further examples, the features extracted at block 210 include frequency-domain representations of any of the above-mentioned quantities. For example, a one-dimensional vector containing a frequency-domain representation of accelerations represented by the motion sensor data can be employed as a feature. The above-mentioned patent publication no. WO 2019/016764 includes a discussion of the generation of frequency-domain feature vectors. In further examples, two or more of the above vectors may be combined into a feature matrix for use as an input to the primary inference model.

Having extracted the features at block 210, the computing device 100 is configured to select a candidate gesture identifier from the preconfigured gestures for which the classifier was trained. That is, the device 100 is configured to execute the primary inference model, based on the parameters stored in the repository 128. Classification may generate, as mentioned earlier, a set of probabilities indicating, for each preconfigured gesture, the likelihood the motion sensor data (as represented by the features extracted at block 210) matches the preconfigured gestures. The probabilities referred to above may also be referred to as confidence levels. An example of output produced by the classification process is shown below in Table 1.

TABLE 1
Example Classification Output

| Gesture A | Gesture B | Gesture C | Gesture D | Gesture E |
|---|---|---|---|---|
| 0.11 | 0.09 | 0.73 | 0.02 | 0.05 |

In the example shown in Table 1 the primary inference model (trained to recognize five distinct gestures) indicated that the features extracted from the motion sensor data have a probability of 11% of matching “Gesture A”, a 9% probability of matching “Gesture B”, and so on. To complete the performance of block 210, the device 100 is configured to select, as the candidate gesture matching the motion sensor data, the gesture identifier corresponding to the greatest probability generated via classification. In the above example, the device 100 therefore selects “Gesture C” (with a probability of 73%) as the candidate gesture identifier.

At block 215, the device 100 is configured to determine whether the confidence level associated with the selected candidate gesture identifier exceeds a predetermined threshold, which may also be referred to as a detection threshold or a primary threshold. The primary threshold serves to determine whether the candidate gesture selected at block 210 is sufficiently likely to match the motion sensor data to invoke gesture-based functionality.

In the present example, the threshold applied at block 215 is 70%, although thresholds greater or smaller than 70% may be applied in other examples. Thus, the determination at block 215 is affirmative, and the device 100 proceeds to block 220. When the determination at block 215 is negative, the candidate gesture identifier is discarded, and the performance of the method 200 may terminate. The device 100 may also, for example, present an alert (e.g. on the display 112) indicating that gesture recognition was unsuccessful.

At block 220, the device 100 is configured to invoke the auxiliary inference model corresponding to the candidate gesture identifier selected at block 210. As noted above, the repository 128 stores parameters defining distinct auxiliary models for each preconfigured gesture. Thus, at block 220 the device 100 retrieves the parameters for the auxiliary model that corresponds to the candidate gesture from block 210 (i.e. Gesture C in this example), and applies the retrieved auxiliary model to at least a subset of the features from block 210.

Applying an auxiliary model to features extracted from motion sensor data generates a score representing a likelihood that the motion sensor data represents the candidate gesture corresponding to the auxiliary model. That is, each auxiliary model does not distinguish between multiple gestures, but rather indicates only how closely the motion sensor data matches a single specific gesture. The output of the auxiliary model may be a probability (e.g. between 0 and 1 or 0 and 100%), but may also be a score without predefined boundaries such as those mentioned above.

At block 225, the device 100 determines whether the score generated via application of the auxiliary model at block 220 exceeds a validation threshold. The validation threshold is selected such that when the determination at block 225 is affirmative, the candidate gesture from block 210 is sufficiently likely to match the motion sensor data to invoke gesture-based functionality. Expressed in terms of probability, for example, the validation threshold may be 80%, although smaller and greater thresholds may also be applied. The validation threshold can also be lower than the detection threshold applied at block 215 in other examples.

When the determination at block 225 is negative, the candidate gesture selection is discarded, and the performance of the method 200 ends, as discussed above in connection with a negative determination at block 215. In other words, a negative determination at block 225 indicates that the candidate gesture selected via application of the primary inference model has not been validated, indicating a likely incorrect matching of an OOV gesture to one of the preconfigured gestures.

When the determination at block 225 is affirmative, on the other hand, the device 100 proceeds to block 230. At block 230 the device 100 is configured to present an indication of the now-validated candidate gesture identifier, for example on the display 112. The candidate gesture identifier may also be presented along with a graphical rendering of the gesture and one or both of the confidence value from block 210 and the score from block 220. The device 100 can also store a mapping of gestures to actions, and can therefore initiate one of the actions that corresponds to the classified gesture. The actions can include executing a further application, executing a command within an application, altering a power state of the device 100, and the like. In other examples, the device 100 can transmit the validated candidate gesture identifier to another computing device for further processing.

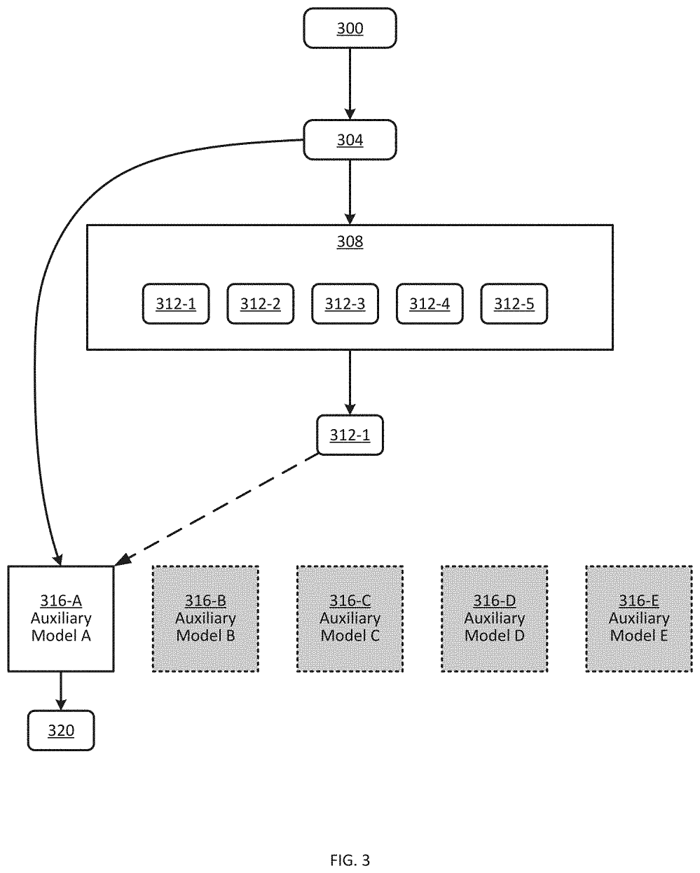

Referring to FIG. 3, a graphical representation of the classification and validation process described above is shown. In particular, motion sensor data 300 is obtained as an input (at block 205). From the motion sensor data 300, the device 100 extracts features 304, and applies the primary inference model 308 to the features 304. The primary inference model generates probabilities 312-1, 312-2, 312-3, 312-4 and 312-5 corresponding to each of the preconfigured gestures (five in this example) for which the primary inference model 308 is trained. In the illustrated example it is assumed that the probability 312-1 is the highest of the probabilities 312, and also satisfies the detection threshold at block 215.

The device 100 therefore activates the corresponding auxiliary model 316-A. The remaining auxiliary models 316-B, 316-C, 316-D and 316-E, corresponding to the other preconfigured gestures, remain inactive in this example. The selected auxiliary model 316-A is applied to the features 304 at block 220, to produce a score 320 that is evaluated at block 225.

Variations to the above systems and methods are contemplated. For example, while the method 200 as described above involves applying the one of the auxiliary models that corresponds to the candidate gesture identified via primary classification, in other embodiments all auxiliary models may be applied to the features extracted from the motion data. In further examples, the auxiliary models may be applied to the features before the primary inference model is applied.

As noted earlier, in some examples the repository 128 may define a plurality of auxiliary models for each preconfigured gesture. For example, for a three-dimensional preconfigured gesture, a separate auxiliary model may be defined for motion in each of three planes (e.g. XY, XZ and YZ). At block 220, each of the auxiliary models corresponding to the candidate gesture are applied to the features from block 210, and a set of scores may therefore be produced. Block 225 may therefore be repeated once for each auxiliary model, and the device 100 may proceed to block 230 only when all instances of block 225 are affirmative.

When the preconfigured gestures include gestures with motion in only two planes as well as gestures with motion in three planes, the features extracted at block 210 may include features representing motion in all three planes. However, when the candidate gesture identifier selected at block 210 includes motion in only two planes, the device 100 may be configured to apply the corresponding auxiliary model to only a subset of the features from block 210, omitting features that define motion in planes that are not relevant to the candidate gesture. The device 100 can determine which portion of the features from block 210 are relevant to the candidate gesture by, for example, consulting a script defining the preconfigured gesture. Examples of such a script are set out in Applicant's patent publication no. WO 2019/016764.

Those skilled in the art will appreciate that in some embodiments, the functionality of the application 124 may be implemented using pre-programmed hardware or firmware elements (e.g., application specific integrated circuits (ASICs), electrically erasable programmable read-only memories (EEPROMs), etc.), or other related components.

The scope of the claims should not be limited by the embodiments set forth in the above examples, but should be given the broadest interpretation consistent with the description as a whole.

1. A method of gesture detection in a controller, comprising:
storing, in a memory connected with the controller:
(i) a primary inference model definition corresponding to a plurality of gesture identifiers, and
(ii) a set of auxiliary model definitions, each corresponding to a respective one of the gesture identifiers;
obtaining, at the controller, motion sensor data;
selecting a candidate gesture identifier from the plurality of gesture identifiers, based on the motion sensor data and the primary inference model definition;
validating the candidate gesture identifier using the auxiliary model definition that corresponds to the candidate gesture identifier; and
when the candidate gesture identifier is validated, presenting the candidate gesture identifier.

2. The method of claim 1, further comprising:
storing, in the memory, a mapping between the gesture identifiers and corresponding actions; and
presenting the candidate gesture identifier by initiating a corresponding one of the actions based on the mapping.

3. The method of claim 1, further comprising:
extracting features from the motion sensor data;
wherein selecting the candidate gesture identifier is based on the features and the primary inference model definition.

4. The method of claim 1, wherein the set of auxiliary model definitions includes, for each of the gesture identifiers, a subset of auxiliary model definitions.

5. The method of claim 1, wherein selecting the candidate gesture identifier includes:
generating a confidence level corresponding to the candidate gesture identifier; and
determining that the confidence level exceeds a detection threshold.

6. The method of claim 1, wherein validating the candidate gesture identifier includes:
generating a likelihood that the motion sensor data corresponds to the candidate gesture identifier; and
determining whether the likelihood exceeds a validation threshold.

7. The method of claim 1, wherein obtaining the motion sensor data includes receiving the motion sensor data from a motion sensor connected to the controller.

8. A computing device, comprising:
a memory storing (i) a primary inference model definition corresponding to a plurality of gesture identifiers, and (ii) a set of auxiliary model definitions, each corresponding to a respective one of the gesture identifiers;
a controller connected with the memory, the controller configured to:
obtain motion sensor data;
select a candidate gesture identifier from the plurality of gesture identifiers, based on the motion sensor data and the primary inference model definition;
validate the candidate gesture identifier using the auxiliary model definition that corresponds to the candidate gesture identifier; and
when the candidate gesture identifier is validated, present the candidate gesture identifier.

9. The computing device of claim 8, wherein the memory stores a mapping between the gesture identifiers and corresponding actions; and wherein the controller is further configured, in order to present the candidate gesture identifier, to initiate a corresponding one of the actions based on the mapping.

10. The computing device of claim 8, wherein the controller is further configured to:
extract features from the motion sensor data;
wherein selection of the candidate gesture identifier is based on the features and the primary inference model definition.

11. The computing device of claim 8, wherein the set of auxiliary model definitions includes, for each of the gesture identifiers, a subset of auxiliary model definitions.

12. The computing device of claim 8, wherein the controller is configured, in order to select the candidate gesture identifier, to:
generate a confidence level corresponding to the candidate gesture identifier; and
determine that the confidence level exceeds a detection threshold.

13. The computing device of claim 8, wherein the controller is configured, in order to validate the candidate gesture identifier, to:
generate a likelihood that the motion sensor data corresponds to the candidate gesture identifier; and
determine whether the likelihood exceeds a validation threshold.

14. The computing device of claim 8, further comprising:
a motion sensor;
wherein the controller is configured, in order to obtain the motion sensor data, to receive the motion sensor data from the motion sensor.

15. A non-transitory computer-readable medium storing computer-readable instructions executable by a controller to:
store (i) a primary inference model definition corresponding to a plurality of gesture identifiers, and (ii) a set of auxiliary model definitions, each corresponding to a respective one of the gesture identifiers;
obtain motion sensor data;
select a candidate gesture identifier from the plurality of gesture identifiers, based on the motion sensor data and the primary inference model definition;
validate the candidate gesture identifier using the auxiliary model definition that corresponds to the candidate gesture identifier; and
when the candidate gesture identifier is validated, present he candidate gesture identifier.
